(19) United States
(12) Patent Application Publication
(10) Pub. No.: US 2007/0137700 A1
(43) Pub. Date: Jun. 21, 2007

(54) Development of an electronic device quality aluminum antimonide (AISb) semiconductor for solar cell applications

(75) Inventors: John W. Sherohman, Livermore, CA (US); Jick Hong Yee, Livermore, CA (US); Arthur W. Coombs III, Patterson, CA (US)

Correspondence Address: Michael C. Staggs;Lawrence Livermore National Laboratory, P.O. Box 808, L-703, Livermore, CA, 94551, US

(73) Assignee: The Regents of the University of California

(21) Appl. No.: 11/305,381

(22) Filed: Dec. 16, 2005

(51) Int. Cl. H01L 31/00

(52) U.S. Cl. 136/262; 136/265

(57) ABSTRACT

For the first time, electronic device quality Aluminum Antimonide (AlSb)-based single crystals produced by controlled atmospheric annealing are utilized in various configurations for solar cell applications. Like that of a GaAs-based solar cell devices, the AlSb-based solar cell devices as disclosed herein provides direct conversion of solar energy to electrical power.

The United States Government has rights in this invention pursuant to Contract No. W-7405-ENG-48 between the United States Department of Energy and the University of California for the operation of Lawrence Livermore National Laboratory.

### BACKGROUND OF THE INVENTION

1. Field of the Invention

The present invention relates to semiconductors. More specifically, the present invention relates to semiconductor structures that include Aluminum Antimonide (AlSb) and lattice matched solid solution semiconductor materials so as to produce solar cells.

2. State of Technology

Solar cells or photovoltaics (PV) manufactured from semiconductor materials are based on absorbing photons of light so as to promote valence electrons of the semiconductor to the conduction band to enable such electrons to move freely through the semiconductor. At the same time, the holes left by the yielded electrons can jump from core to core, thus forming positive charge carriers which can also move easily through the valence band of the semiconductor material. Such a mechanism thus generates electron-hole pairs so as to produce a current that can be harvested to charge batteries, operate motors, and to power a wide variety of electrical loads.

Because of the concerns over limited resources, efforts have been ongoing to increase the output and/or the efficiency of PV cells. One such arrangement includes stacking materials to create multi-junctions (grouping a predetermined number, often greater than about 2, different p-n junction semiconductor materials) so that predetermined materials having different energy bandgaps can absorb a different part of the energy distribution from the sun. In such an arrangement, the top layers absorb higher-energy photons, while transmitted lower-energy photons are absorbed by the lower layers of the configured device. Background information for such devices is described and claimed in U.S. Pat. No. 6,891,869 B2, entitled “Wavelength-Selective Photonics Device,” issued May 10, 2005 to Augusto, including the following, “A device comprising a number of different wavelength-selective active-layers arranged in a vertical stack, having band-alignment and work-function engineered lateral contacts to said active-layers, consisting of a contact-insulator and a conductor-insulator. Photons of different energies are selectively absorbed in or emitted by the active-layers. Contact means are arranged separately on the lateral sides of each layer or set of layers having the same parameters for extracting charge carriers generated in the photon-absorbing layers and/or injecting charge carriers in the top photon-emitting layers. The device can be used for various applications: wavelength-selective multi-spectral solid-state displays, image-sensors, light-valves, light-emitters, etc. It can also be used for multiple-band gap solar-cells. The architecture of the device can be adapted to produce coherent light.”

In addition, solar cells, such as, GaAs (a=5.6533 Å) and Ge (a=5.6575 Å) stacked devices have been arranged in lattice matched configurations (lattice mismatch is on the order of 0.074%) so as to minimize surface dislocations, i.e., crystal defects at the interface of the stacked layers. The presence of such crystal defects reduces the minority-carrier lifetimes in the bulk of the layers, increases the surface recombination velocity at interfaces and creates possible shunting paths, all of which can reduce the efficiency of PV devices, and in general, degrade device performance. Further, multi-junction solar cells and other optoelectronic devices having these crystal defects degrade under radiation.

Background information for lattice-matched (PLM) semi-conductor layers is described in U.S. Pat. No. 6,586,669 B2, entitled “Lattice-Matched Semiconductor Materials for Use in Electronic or Optoelectronic Devices,” issued Jul. 1, 2003 to King, et al, including: “In this context, PLM means that the lattice mismatch between the PLM cell and growth substrate is less than 0.074%. If specified, PLM may also refer to a difference in lattice mismatch between the PLM cell and an adjacent cell of less than 0.074%.” Such lattice mismatching is emphasized in a 2005 Solar Energy article by M. Yamaguchi et al, entitled, “Multi-junction III-V solar cells: current status and future potential,” by the following: “Although 0.08% lattice-mismatch between GaAs and Ge was thought to be negligibly small, misfit-dislocations were generated in thick GaAs layers and deteriorated cell performance.”

However, in the context of solar cell performance, it is reported by Burnett in a 2002 document entitled, ‘The Basic Physics and Design of Multijunction Solar Cells” that “work at NREL showed that lattice mismatching as low as ±0.01% causes significant degradation of photovoltaic quality.” It is, therefore, very important in multi-junction solar cell operation to use semiconductor compositions that are latticed matched.

Such multi-junction lattice matched cell layers can be stacked mechanically or the layers can be grown monolithically, typically by metal-organic vapor phase epitaxy (MOVPE) or molecular beam epitaxy (MBE). Background information on similar lattice matched devices can be found in U.S. Pat. No. 6,300,558 B1, entitled “The present invention relates to a high efficiency solar cell that can be used as an energy source of an artificial satellite, etc. and, more particularly, a lattice matched solar cell using group III-V compound semi-conductor, epitaxially grown on a germanium (Ge) substrate, and a method for manufacturing the same.”

Accordingly, a need exists for solar cell configurations that include controlled atmospherically annealed high purity AlSb single crystals so as to efficiently couple the sun's energy distribution. The present invention is directed to such a need.

### SUMMARY OF THE INVENTION

Accordingly, the present invention provides a controlled atmospheric annealed single crystal AlSb substrate host layer material coupled to one or more solid-solution semiconductor materials, wherein each of the one or more solid-solution semiconductor materials further include a lattice parameter so as to produce a substantially lattice-matched configuration.

Another aspect of the present invention is to provide homojunction solar cell configured from a controlled atmospheric annealed single crystal AlSb material.

A further aspect of the present invention is to provide a method of forming a homojunction solar cell that includes: providing high-purity single crystal ingots of AlSb; forming one or more wafers from the high-purity single crystal ingots; providing controlled atmospheric annealing of the single crystal wafers to adjust the stoichiometry; positioning dopants in the wafers so as to form predetermined p-n junctions; surface passivating the single crystal wafers, e.g., using an oxide layer; forming contacts on predetermined regions of the solar cell; and utilizing antireflection technologies and packaging to provide a final product.

A final aspect of the present invention is to provide a method for producing a solar cell that includes: providing a controlled atomospheric annealed single crystal AlSb substrate; wherein the AlSb substrate is configured as an active host layer; and coupling one or more solid-solution semiconductor materials with the controlled atomospheric annealed single crystal AlSb active host layer, wherein each of the one or more solid-solution semiconductor materials further include a lattice parameter so as to produce a substantially lattice-matched configuration.

Accordingly, the present invention provides a controlled atmospheric annealed AlSb single crystal arranged as an active host material for use as a solar cell in arrangements that includes, homojunctions, heterojunctions, multi-junctions, quantum wells, and quantum dot structures. Such AlSb-based solar cell devices can be used in terrestrial solar cell applications. Moreover, because of the high energy band-gap of the AlSb material of the present invention, AlSb-based solar cell devices can also be utilized in concentrator solar cell applications

### BRIEF DESCRIPTION OF THE DRAWINGS

The accompanying drawings, which are incorporated into and form a part of the disclosure, illustrate an embodiment of the invention and, together with the description, serve to explain the principles of the invention.

FIG. 1 shows the space solar spectrum of the sun's light above the Earth's upper atmosphere and the terrestrial solar spectrum as received on Earth

FIG. 2(a) illustrates a basic example p-n homojunction solar cell of the present invention.

FIG. 2(b) illustrates heterostructure device of the present invention having an AlSb host layer coupled to a lattice matched III-V semiconductor.

FIG. 3(a) illustrates an example lattice matched three layer solar cell.

FIG. 3(b) illustrates an example of a lattice matched four layer solar cell device whereby an AlGaInSb compositional layer is used to provide a predetermined intermediate bandgap.

FIG. 4(a) shows an energy bandgap diagram to illustrate a quantum well solar device of the present invention.

FIG. 4(b) illustrates a quantum dot solar cell.

### DETAILED DESCRIPTION OF THE INVENTION

Referring now to the following detailed information, and to incorporated materials; a detailed description of the invention, including specific embodiments, is presented. The detailed description serves to explain the principles of the invention.

Unless otherwise indicated, all numbers expressing quantities of ingredients, constituents, reaction conditions and so forth used in the specification and claims are to be understood as being modified in all instances by the term “about”. Accordingly, unless indicated to the contrary, the numerical parameters set forth in the specification and attached claims are approximations that may vary depending upon the desired properties sought to be obtained by the subject matter presented herein. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the subject matter presented herein are approximations, the numerical values set forth in the specific examples are reported as precisely as possible. Any numerical value, however, inherently contain certain errors necessarily resulting from the standard deviation found in their respective testing measurements.

General Description

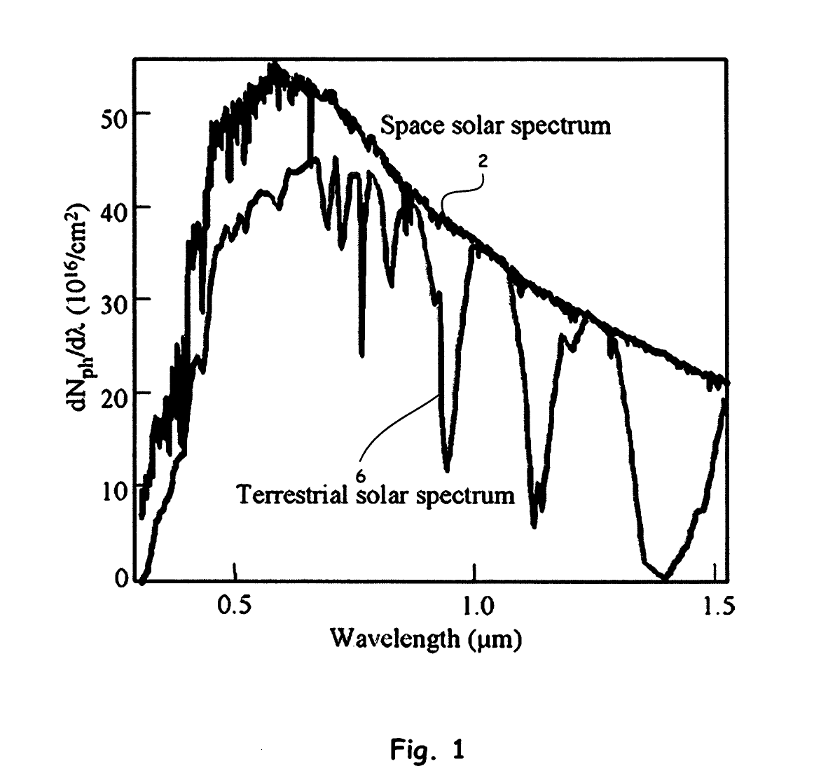

FIG. 1 shows the space solar spectrum 2 of the sun's light above the Earth's upper atmosphere and the terrestrial solar spectrum 6, as received on Earth. As indicated, the solar spectrum peak region is from about 0.4 μm to about 0.7 μm, which shows that photons in the visible and surrounding regions are emitted more than any other part of the sun's electromagnetic spectrum. FIG. 1 also shows that there are a large number of photons in the infrared region from 0.7 to 10 μm and that very little light from the sun contains wavelengths shorter than 0.3 μm (i.e., photon energy greater than about 4 eV). The difference in the space 2 and terrestrial 6 solar spectra, as shown in FIG. 1, is due to photons being absorbed by atmospheric gases such as ozone (O₃, which absorbs higher-energy light below 0.4 μm) and water vapor (photons with wavelengths near 0.9, 1.1, and 1.4 μm). The solar conversion efficiency for any material is therefore greatest for photon energies equal to its bandgap. For the terrestrial solar spectrum 6, the optimal band gap for solar energy conversion is about 1.5 eV. The optimal bandgap for the space solar spectrum 2, is about 1.6 eV, i.e., about the 1.62 eV indirect bandgap of AlSb.

Like Si and Ge, AlSb has an indirect energy band gap. Like GaAs, the energy band gap (Eg) of AlSb at 1.62 eV, provides for a very good power match to the solar spectrum. Consequently, AlSb represents a semiconductor that can have the favorable solar cell qualities of Si (i.e., indirect Eg, implying long free carrier lifetimes and carrier generation well below the surface) and the favorable solar cell quality of GaAs (i.e., high Eg, providing good power matching for efficient solar energy conversion). Because its energy bandgap is slightly higher than GaAs, AlSb also has a good terrestrial solar spectrum power match. However, in space, the power match of AlSb to the solar spectrum is very good, representing, theoretically, near maximum solar energy conversion efficiency. An AlSb concentrator solar cell, due to its higher energy bandgap, has the potential to operate at higher solar conversion efficiency than a GaAs concentrator solar cell. Likewise, because of its indirect energy bandgap and the potential to have free carrier recombination loses on the order of Si, high temperature operation of AlSb would reduce the amount of solar cell surface required of Si to produce an equivalent power output.

With respect to depth of penetration for received photons (i.e., absorption depth), for direct bandgap semiconductors, such as, GaAs, photon absorption takes place very close to the surface. Due to its direct energy bandgap, the GaAs intrinsic absorption coefficient rises sharply with photon energy, which causes free carrier generation to occur within several microns of the surface. In addition, the direct energy bandgap results in the electron and hole carriers having very short lifetimes (nanoseconds). This combination of very short lifetimes and near surface generation can lead to the loss of free carriers by bulk and surface recombination. To produce a high efficient GaAs solar cell, the thickness of the cell is made very thin (shallow junction depth of 0.5 microns or less) and the surface must be very clean to minimize surface recombination states, which arise from “dangling bonds,” chemical residues, metal precipitates, native oxides, and the like.

Photon absorption in indirect semiconductors, such as, Si, may extend into the bulk at distances reaching 100 μm or more before full absorption. Consequently, like Si, which is an indirect bandgap semiconductor, a solar cell of AlSb requires thicker material for photon absorption than direct bandgap semiconductors, e.g., GaAs. This means that electron-hole pairs generated by photons absorbed deep in AlSb will be collected in the bulk crystal when they reach the depletion region of the p-n junction solar cell. It is important, therefore, that an indirect bandgap semiconductor solar cell is of high quality (carrier recombination is minimized) to obtain high solar energy conversion.

The present invention provides such a high quality AlSb solar cell that includes processing high purity as-grown AlSb single crystals that are stoichiometrically controlled using a multiphase atmospheric annealing heat treatment. Such an atmospheric controlled annealing heat treatment enhances the quality of the as-grown crystals by decreasing the intrinsic native defect concentration and thereby extending the lifetime of the carriers to values expected of indirect bandgap material such as Si and Ge. By utilizing such a treatment process, electronic device quality single crystals of AlSb are produced to form solar cell devices for efficient capitalization of the sun's space and terrestrial solar energy spectra, as shown in FIG. 1.

The AlSb single crystal active host substrate as disclosed herein, which can be arranged with a substantially uniform low resistivity (ρ) of often less than about 10 Ω·cm by doping methods known to one of ordinary skill in the art during the growth process (as measured over the entire produced substrate at room temperature (300 K°)), are often produced by a Czochralski (CZ) growth technique. However, other growth methods such as, but not limited to, a Traveling Heating Method (THM), capable of producing quality crystals may also be employed. A detailed disclosure of producing similar high-quality single crystal materials using controlled atmospheric annealing is described in U.S. Pat. No. 6,887,441 B2, titled “High Resistivity Aluminum Antimonide Radiation Detector” by Sherohman et al., assigned to the assignee of the present invention, the disclosure herein incorporated by reference in its entirety. Moreover, the controlled atmospheric annealed single crystal materials, as disclosed herein, can include a beneficial thermal oxide passivation layer having oxides of predominantly aluminum and antimony and a buffer layer can also be designed into the present invention to provide electrical isolation and/or surface smoothing.

The arrangements disclosed herein, in addition to homojunction devices, include stacked materials configured as heterojunction devices, i.e., where the junction is formed by contacting two different semiconductors or as a multijunction device, i.e., a stack of individual single-junction cells in descending order of bandgap (Eg), wherein the top cell captures the high-energy photons and passes the rest of the photons on to be absorbed by lower-bandgap cells. In addition, other arrangements disclosed herein, include heterostructure quantum well and quantum dot solar cell devices. Such multifunction and heterostructure cell arrangements as disclosed herein, can include one or more thin layers of solid solutions greater than 10 Å, often between about 10 Å and up to about 2 μm, of the following materials, such as, but not limited to, Aluminum Antimonide (AlSb), Gallium Antimonide (GaSb), Indium Antimonide (InSb), Indium Arsenide (InAs), Zinc Telluride (ZnTe), and Cadmium Telluride (CdTe) in addition to binary compounds and/or related ternary and quaternary alloys of such materials. For example, given a selected energy bandgap goal, a solid solution formed from AlSb, GaSb, and InSb can be achieved to provide a lattice match to AlSb to less than about 0.01%. Similarly, a higher energy bandgap than AlSb can be obtained with a solid solution of ZnTe and CdTe that provides a lattice match to AlSb to less than about 0.01%.

Such a single crystal material and variations thereof of the present invention is thus beneficial in the design and fabrication of solar cell devices, such as, but not limited to, single-junction solar cells (e.g., homojunction and heterojunction), active host substrates for multifunction solar cell devices, and active host substrates for lattice matched 6.1-Å family heterostructure quantum well and quantum dot solar cell devices so as to efficiently capitalize on the sun's emitted solar spectra, as shown in FIG. 1.

Specific Description

A basic solar cell includes a junction formed between n-type and p-type semiconductors, either of the same material (homojunction), or two different materials (heterojunction). Like silicon, AlSb can be doped to form both p-type and n-type material to create a homojunction. Likewise, p-type or n-type AlSb can be used with another doped semiconductor to create a heterojunction. Similarly, like GaAs, AlSb can be layered by other lattice matched semiconductor materials to form multi-junction solar cells, including both quantum well and quantum dot heterostructure solar cells. AlSb type solar cell devices can be used in non-concentrated and solar concentrated solar cell applications, both terrestrially and in space.

Homojunction Device

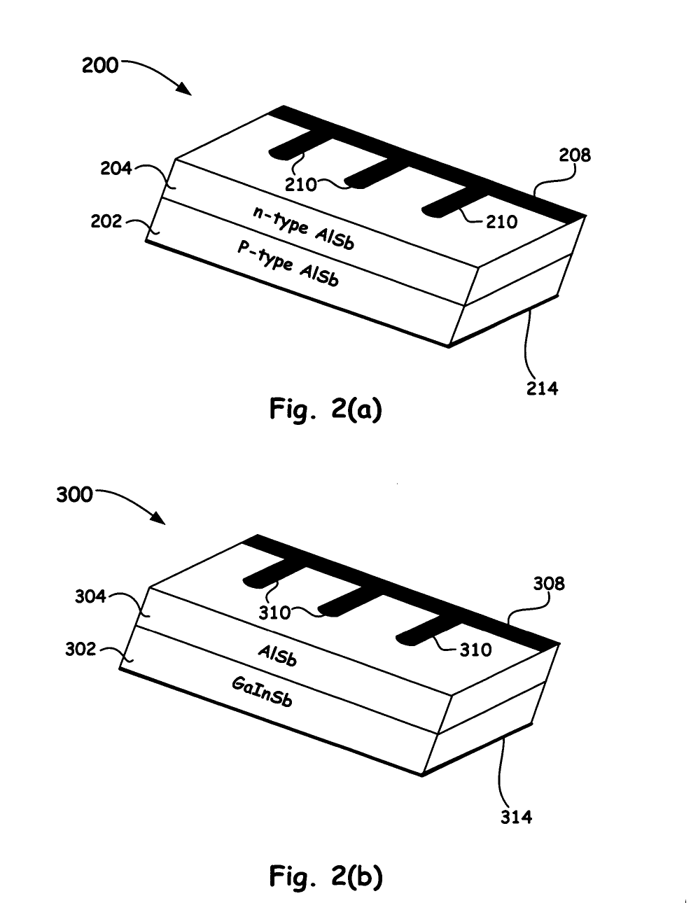

FIG. 2(a) shows a basic example p-n homojunction solar cell of the present invention and generally designated by the reference numeral 200, which can include as one embodiment, a p-type AlSb material 202, an n-type AlSb material 204, a front ohmic contact stripe 208 coupled to ohmic fingers 210, and a back ohmic contact 214. In addition to having applied anti-reflection coatings on solar energy receiving surfaces (e.g., material 204) to increase efficiency, design parameters, such as, but not limited to, increasing the depth of the p-n junction below a cell's surface, and varying the amount and distribution of dopant atoms by methods known to one of ordinary skill in the art on either side of a predetermined p-n junction(s), in addition to producing a substantially pure AlSb single crystal of the cell are capable of being altered so as to also increase the overall conversion efficiency of solar cell embodiments of the present invention.

An example method of forming such a high-efficient AlSb homojunction solar cell, similar to that shown in FIG. 2(a), which can be constructed to principles of the present invention, includes: growing p- or n-type high-purity single crystal ingots of AlSb; slicing the ingots to form wafers; annealing such single crystal wafers to adjust the stoichiometry; forming predetermined p-n junctions in the wafers by positioning dopants using methods known to those of ordinary skill in the art of semiconductor doping to form p-or n-type single crystals (e.g., for a p-type wafer, an element is chosen that will form n-type AlSb and for an n-type wafer, an element is chosen that will form p-type AlSb); surface passivating the wafers, e.g., by forming an oxide layer during one or more heat treatments; forming contacts on both the p-type and n-type regions of the cell using known state of the art methods; and by utilizing antireflection technologies and packaging to provide a final product.

Heterojunction Device

A heterojunction solar cell includes two different semiconductors forming a p-n junction. An advantage exists in the heterojunction cell over a homojunction cell if the top layer semiconductor has a larger bandgap than the bottom semiconductor. In this case, photons with energy at or greater than the top bandgap are largely absorbed by the top semiconductor. For lower energy photons, the top semiconductor is a “window” to the bottom semiconductor. The bottom semiconductor absorbs the lower energy photons as determined by its bandgap. The approach of forming a heterojunction solar cell enhances the short wavelength response.

The main difficulty of a heterojunction solar cell is using semiconductors that have a good lattice match. As discussed above in the background materials, a two cell layer arrangement having GaAs (a=5.653 Å) configured as the top semiconductor with Ge (a=5.660 Å) as the bottom semiconductor provides a very good lattice match at 0.074%. However, as reported by Burnett in a 2002 document entitled, ‘The Basic Physics and Design of Multijunction Solar Cells”, research at NREL showed that lattice mismatching as low as ±0.01% causes significant degradation of photovoltaic quality of the solar cell. Likewise, in the present invention, as shown in FIG. 2(b), an AlSb heterojunction device, generally designated as reference numeral 300, can be fabricated using substantially lattice matched materials (i.e., less than about a 0.01% lattice mismatch), such as, for example, using p-or n-type Ga₁₋ₓInₓSb as the bottom semiconductor 302 and n-or p-type AlSb as the top layer 304. For illustration purposes, by adding about 10% InSb to GaSb, the compound Ga_{0.90}In_{0.10}Sb can be latticed matched to the AlSb layer. The bandgap of such a compound is about 0.63 eV.

In the heterojunction device, a tunnel junction to reduce interconnection loss (reduce both optical and electrical power loss) may be used to increase the solar cell efficiency between the AlSb and G_{0.90}In_{0.10}Sb layer. Similar to the homojunction device 200, as shown in FIG. 2(a), a front ohmic contact stripe 308 coupled to ohmic fingers 310, and a back ohmic contact 314 in addition to having applied anti-reflection coatings (not shown) on solar energy receiving surfaces (e.g., material 304) are also capable of being configured with heterojunction device 300 so as to respectively provide circuit contacts for predetermined loads and to increase efficiency.

Multi-Junction Solar Cell

Multi-junction solar cells or tandem cells of the present invention include layers of predetermined semiconductors stacked on top of each other with decreasing bandgaps. Each cell layer is able to convert a different wavelength of the light spectrum into electricity. The top layers absorb higher-energy photons, while transmitting lower-energy photons to be absorbed by the lower layers of the cell. The multi-junction cell layers can be stacked mechanically or the layers can be grown monolithically. In the monolithic approach, one complete solar cell is made first, and then the layers for the other cells are grown or deposited typically by epitaxial growth methods, more often by metal-organic vapor phase epitaxy (MOVPE) or molecular beam epitaxy (MBE), growth methods that are well known and understood by those of ordinary skill in the art. Such a process forms the multijunction layered solar cell structure.

To achieve high conversion efficiency it is required that these layered semiconductors are substantially “lattice matched” to less than about 0.01% of a predetermined material's lattice parameter. Latticed matched layers significantly reduce surface dislocation defects in the crystal structure, which can impede cell performance. Another “matching” criterion in such devices is to “current match” such layers. Because each layer has a different rate of photon absorption, the thickness of each layer is optimized to ensure each layer, which is series connected, generates the same amount of electrical current.

As in the case of the heterostructure shown in FIG. 2(b), the top layer 304 and the bottom layer 302 can be individual single-junction cells (i.e., each layer having its own p-n junction) representing a two junction solar cell. The two-junction solar cell, generally designated as reference numeral 300 in FIG. 2(b), can be fabricated using substantially lattice matched materials (i.e., less than about a 0.01% lattice mismatch), such as, for example, a layer of Ga_{0.90}In_{0.10}Sb as the bottom cell 302 and AlSb as the top layer cell 304.

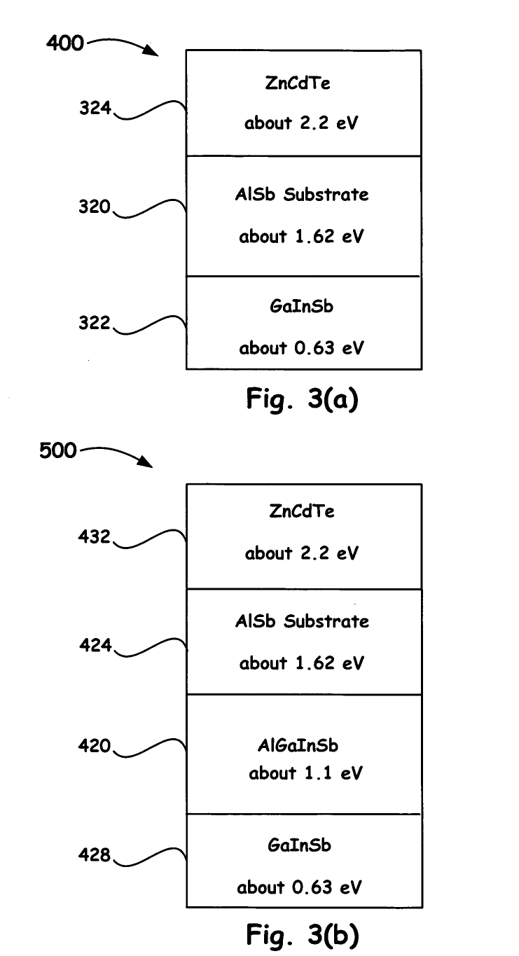

For illustration purposes, FIG. 3(a) shows an example three layer solar cell of the present invention, generally designated by the reference numeral 400, which includes an AlSb single crystal wafer host cell wafer 320 sandwiched between a substantially lattice matched GaInSb cell layer 322 (e.g., Ga_{0.90}In_{0.10}Sb) and a substantially lattice matched ZnCdTe layer 324. In the case of the substantially lattice matched ZnCdTe layer 324, about 10% CdTe can be added to ZnTe to form, for example, a Zn_{0.90}Cd_{0.10}Te compound having a band gap of about 2.2 eV. In constructing such an example three layer multi-junction solar cell 400, the lattice matched GaInSb cell layer 322 is deposited on the AlSb host cell wafer 320, e.g., by MBE, so as to form the bottom layer. Subsequently, AlSb host cell wafer 320 can be turned over with lattice matched p- or n-type ZnCdTe 324 deposited as the top layer to form a heterostucture with the p- or n-type side of the p-n junction of the AlSb host cell wafer 320. Alternatively, the latticed match ZnCdTe 324, if deposited as a p-n junction layer, could be an individual single junction cell top layer. The result is a three layer solar cell with bandgaps of about 2.2 eV (bandgap at 300° K) for the lattice matched ZnCdTe (direct bandgap) layer, about 1.62 eV for AlSb (indirect bandgap) and about 0.63 eV for the lattice matched GaInSb (direct bandgap) layer. Since such layers are lattice matched to AlSb and all have the zincblende crystal structure, this multi-layer device is expected to have a solar concentrator conversion efficiency as high as or greater than currently utilized GaInP/GaAs/Ge devices. As in the case of GaInP/GaAs/Ge solar devices, tunnel junctions may be used between the ZnCdTe/AlSb/GaInSb layers to increase the solar cell efficiency by reducing interconnection losses. In addition, similar to the devices as discussed above in FIGS. 2(a) and 2(b), the example device as shown in FIG. 3(a) may have applied anti-reflection coatings (not shown) but may also contain metal contact layers (not shown) on any of the layers so as to utilize the produced electricity.

FIG. 3(b) shows another exemplary novel solar cell multi-layer device, generally designated by the reference numeral 500, using single crystal AlSb material as part of the configuration. Since solid solutions can be formed between AlSb, GaSb, and InSb, a quarternary compound lattice matched to AlSb can be made for example, by molecular beam epitaxy (MBE) deposition with a bandgap of about 1.1 eV. Such a beneficial material includes, for example, an AlGaInSb semiconductor 420, such as, for example, a quarternary composition of about Al_{0.50}Ga_{0.45}In_{0.05}Sb that is lattice matched to AlSb by methods of the present invention. Such a lattice matched quarternary compound is often beneficially placed between an AlSb layer 424 and the lattice matched GaInSb layer 428. On the other side of the AlSb 424 wafer substrate is the lattice matched ZnCdTe semiconductor material 432, as discussed above. Once again, the example device as shown in FIG. 3(b) may have tunnel junctions between the layers to increase the solar cell efficiency by reducing interconnection losses. Also, the example device shown in FIG. 3(b) may have applied anti-reflection coatings (not shown) but may also contain metal contact layers (not shown) on any of the layers so as to utilize the produced electricity.

Quantum Well Devices

It is known to one of ordinary skill in the art that quantum wells can be added to a single bandgap p-n junction solar cell. Generally, if the charge carrier in a solid is confined to a semiconductor layer, e.g., 6.1 Angstrom family III-V semiconductor heterostructures of the present invention as discussed above, having a thickness of the order of the de Broglie wavelength of elementary excitations (or mean free path, whichever is shorter), then, in accordance with the quantum mechanics, quantum-size effects must be observed. In such an arrangement, lower energy photons that are not captured by the single bandgap material can be absorbed by the quantum well layers. The charge carriers produced in such a quantum well structure escape and add to the photocurrent output of the cell.

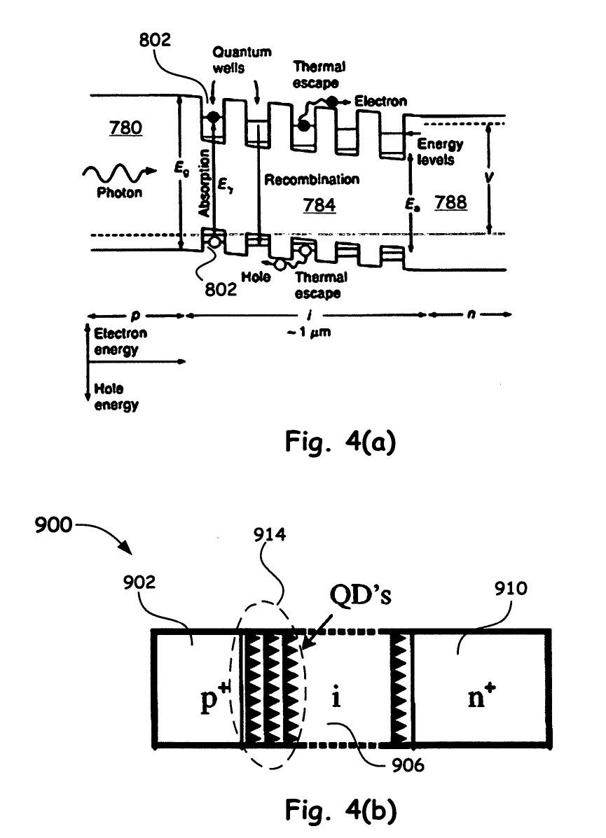

FIG. 4(a) shows an energy bandgap diagram of a quantum well solar cell that utilizes such a mechanism so as to be adapted with any of the 6.1 Angstrom heterostructure arrangements as discussed above. The device, as shown in FIG. 4(a) is a p-i-n solar cell (p region 780, i region 784, and n region 788) with a multi-quantum well system 802 added to the intrinsic region (the “i” 784 in p-i-n). Because of the importance of lattice matching in solar cell operation, the material forming the quantum well with AlSb is beneficially lattice matched to AlSb. Such a quantum well matching with AlSb has been determined for high electron mobility transistor (HEMT) devices by M. J. Yang, “Photoluminescence of InAs₁₋ₓSbₓ/AlSb single quantum wells: Transition from type-II to type-I band alignment,” J. Appl. Phys., volume 87, No. 11, 8192 (2000). The composition of about InAs_{0.82}Sb_{0.18} is reported to be lattice matched to AlSb to form lattice matched quantum wells that are more favorable for HEMT operation. In producing an AlSb quantum well solar cell device, an example composition of about InAs_{0.82}Sb_{0.18} can be used to form lattice matched quantum wells within the intrinsic region of the AlSb p-n junction as represented in FIG. 4(a).

Quantum Dot Solar Cell

Similar to the semiconductor p-i-n quantum well solar cell, as shown in FIG. 4(a) and as discussed above, the present invention can be arranged as a semiconductor p-i-n quantum dot solar cell. FIG. 4(b) shows a basic example of such a p-i-n cell (p region 902, i region 906, and n region 910), generally designated by the reference numeral 900, with multi-quantum dot layers 914 (e.g., as shown within the dashed ellipse) deposited in the intrinsic region 906.

In such an arrangement, a photon with sufficient energy will dislodge an electron from an atom in a dot, generating an electron-hole pair. Because the dots occupy so little space, electrons and holes get boxed in, or quantum-confined. Because of this confinement, an electron or hole liberated by a photon is restricted to a set of energy levels within the quantum dot. The smaller the dot, the wider apart the energy levels become and the greater the dot's energy bandgap. By controlling the dot size and density in the intrinsic region, the absorption of the lower energy photons is tuned in the present invention to increase the solar conversion efficiency. As an example material that can be utilized as quantum dots in the heterostructure arrangements discussed above, include, but are not limited to, InAs. InAs has a very low bandgap (E_{g}=0.36 eV), and accordingly, the size and shape of the InAs dots can be tuned to cover a range of bandgaps and thus a predetermined portion of the light absorption spectrum that are of particular importance for solar cells of the present invention. Specifically, because InAs (a=6.058 Å) is a member of the 6.1-Å family of semiconductors, single crystal AlSb materials as disclosed herein can be arranged as a working substrate to provide lattice matching for a quantum dot solar cell using, for example, InAs. However, because of the importance of lattice matching in the operation of solar cells, as in the case of AlSb quantum well solar cells, lattice matched quantum dots should be used in the AlSb quantum dot solar cell. Beneficial quantum dots as disclosed herein include, but is not limited to the compound of about InAS_{0.82}Sb_{0.18} in the intrinsic region of AlSb to provide lattice matching.

It is to be understood that the number of semiconductor layers and the variations disclosed herein are not limited to these numbers of layers and/or variations. While the example arrangements of the invention are described, various modifications may be made in such arrangements to cover all modifications, equivalents, and alternatives falling within the spirit and scope of the invention as defined by the following appended claims.

The invention claimed is:

1. A solar cell, comprising:
a controlled atmospheric annealed single crystal AlSb substrate material; wherein said AlSb material is utilized as an active host layer; and
one or more solid-solution semiconductor materials coupled to said annealed single crystal AlSb active host layer, wherein each of said one or more solid-solution semiconductor materials further comprise a lattice parameter so as to produce a substantially lattice-matched configuration.

2. The solar cell of claim 1, wherein said substantially lattice matched configuration comprises less than about a 0.01% lattice mismatch.

3. The solar cell of claim 1, wherein said one or more solid-solution semiconductor materials comprise at least two materials selected from: Aluminum Antimonide (AlSb), Gallium Antimonide (GaSb), Indium Antimonide (InSb), Indium Arsenide (InAs), Zinc Telluride (ZnTe), and Cadmium Telluride (CdTe).

4. The solar cell of claim 3, wherein said selected one or more solid-solution semiconductor materials further comprise binary compounds and/or related ternary and quaternary alloys.

5. The solar cell of claim 1, wherein said one or more solid-solution semiconductor materials comprise substantially lattice matched materials selected from the III-V 6.1 Angstrom family of materials.

6. The solar cell of claim 1, wherein said one or more solid-solution semiconductor materials comprise substantially lattice matched materials selected from the II-VI family of materials.

7. The solar cell of claim 1, wherein said one or more solid-solution semiconductor materials comprise predetermined thicknesses so as to provide substantially an equal amount of current.

8. The solar cell of claim 1, wherein said controlled atmospheric annealed host layer comprises an n-,or p-type host layer.

9. The solar cell of claim 1, wherein said one or more solid-solution semiconductor materials comprises an n- or p-type material.

10. The solar cell of claim 1, wherein said AlSb active host layer can be interposed between substantially lattice matched ZnCdTe and GaInSb materials.

11. The solar cell of claim 1, wherein said AlSb active host layer can be interposed between a substantially lattice matched layer of ZnCdTe and substantially lattice matched layers comprising AlGaInSb and GaInSb.

12. The solar cell of claim 1, further comprising at least one arrangement selected from: antireflection coatings, buffer layers, ohmic contacts, tunnel junctions, and passivation layers.

13. The solar cell of claim 12, wherein said buffer layers are arranged so as to provide electrical isolation and/or surface smoothing.

14. The solar cell of claim 1, wherein said solar cell comprises a heterostructure.

15. The solar cell of claim 14, wherein said heterostructure further comprises a top layer having a larger bandgap than the bottom layer.

16. The solar cell of claim 1, wherein said solar cell comprises a quantum device selected from: a quantum well solar cell and a quantum dot solar cell.

17. The solar cell of claim 1, wherein said solar cell comprises a multi-junction solar cell.

18. The solar cell of claim 17, wherein said multi-junction solar cell further comprises a stack of individual single-junction cells configured in descending order of bandgap (Eg).

19. A homojunction solar cell, comprising:
a controlled atmospheric annealed single crystal AlSb material; and
a predetermined number of p-type and n-type dopants diffused within said single crystal AlSb material so as to produce a p-n junction.

20. The solar cell of claim 19, further comprising at least one arrangement selected from: antireflection coatings, ohmic contacts, buffer layers, tunnel junctions and passivation layers.

21. A method for producing a homojunction solar cell, comprising:
providing high-purity single crystal ingots of AlSb;
forming one or more wafers from said high-purity single crystal ingots;
providing controlled atmospheric annealing of said single crystal wafers to adjust the stoichiometry;
positioning dopants in said wafers so as to form predetermined p-n junctions;
surface passivating said single crystal wafers;
forming contacts on predetermined regions of said solar cell; and
utilizing antireflection technologies and packaging to provide a final product.

22. The method of claim 21, wherein high purity single crystal ingots comprise an n- or p-type single crystal ingot.

23. A method for producing a solar cell, comprising:
providing a controlled atomospheric annealed single crystal AlSb substrate; wherein said AlSb substrate is configured as an active host layer; and
coupling one or more solid-solution semiconductor materials with said controlled atomospheric annealed single crystal AlSb active host layer, wherein each of said one or more solid-solution semiconductor materials further comprise a lattice parameter so as to produce a substantially lattice-matched configuration.

24. The method of claim 23, wherein said substantially lattice matched configuration comprises less than about a 0.01% lattice mismatch.

25. The method of claim 23, wherein said one or more solid-solution semiconductor materials comprise at least two materials selected from: Aluminum Antimonide (AlSb), Gallium Antimonide (GaSb), Indium Antimonide (InSb), Indium Arsenide (InAs), Zinc Telluride (ZnTe), and Cadmium Telluride (CdTe).

26. The method of claim 25, wherein said selected solid-solution semiconductor materials further comprise binary compounds and/or related ternary and quaternary alloys.

27. The method of claim 23, wherein said one or more solid-solution semiconductor materials comprise predetermined thicknesses so as to provide substantially an equal amount of current.

28. The method of claim 23, wherein said one or more solid-solution semiconductor materials further comprise epitaxy layers.

29. The method of claim 23, further comprising at least one arrangement selected from: antireflection coatings, buffer layers, ohmic contacts, tunnel junctions, and passivation layers.

30. The method of claim 29, wherein said buffer layers are arranged so as to provide electrical isolation and/or surface smoothing.

31. The method of claim 23, wherein said solar cell comprises a heterostructure.

32. The method of claim 31, wherein said heterostructure further comprises a top layer having a larger bandgap than the bottom layer.

33. The method of claim 23, wherein said solar cell comprises a quantum device selected from: a quantum well solar cell and a quantum dot solar cell.

34. The method of claim 23, wherein said solar cell comprises a multi-junction solar cell.

35. The method of claim 34, wherein said multi-junction solar cell further comprises a stack of individual single-junction cells in descending order of bandgap (Eg).

36. The method of claim 23, wherein said controlled atmospheric annealed host layer comprises an n- or p-type host layer.

37. The method of claim 23, wherein said one or more solid-solution semiconductor materials comprises an n- or p-type material.

38. The method of claim 23, wherein said solid-solution semiconductor materials comprise substantially lattice matched materials selected from the III-V 6.1 Angstrom family of materials.

39. The method of claim 23, wherein said solid-solution semiconductor materials comprise substantially lattice matched materials selected from the II-VI family of materials.
